(19) United States
(12) Patent Application Publication
(10) Pub. No.: US 2022/0418167 A1
(43) Pub. Date: Dec. 29, 2022

(54) RACK ARCHITECTURE FOR MULTIPLE MIXED THERMAL SYSTEMS

(71) Applicant: Baidu USA LLC, Sunnyvale, CA (US)

(72) Inventor: Tianyi GAO, Sunnyvale, CA (US)

(21) Appl. No.: 17/358,664

(22) Filed: Jun. 25, 2021

(51) Int. Cl. H05K 7/20

(52) U.S. Cl. CPC H05K 7/20781; H05K 7/20318; H05K 7/20818; H05K 7/20281; H05K 7/20272

(57) ABSTRACT

An electronic rack cooling system is disclosed that includes both a two-phase cooling system having a first cooling loop and a single-phase system comprising a second cooling loop. A main coolant source, such as a facility cooling fluid is coupled to a condenser unit of the two-phase cooling system. A branch off of the facility cooling fluid is directed to the single-phase cooling loop. The coolant flow to the single-phase cooling loop is controlled by a flow control value and a coolant pump. The facility cooling fluid is managed between the single-phase loop and phase change loop. A rack management unit in the electronic rack controls facility cooling fluid flow rate using the flow control device and pump.

### FIELD OF THE INVENTION

Embodiments of the present invention relate generally to data center cooling. More particularly, embodiments of the invention relate to a multiple phase, multiple cooling system architecture for cooling servers in racks, clusters, or a data center.

### BACKGROUND

Cooling is a prominent factor in a computer system and data center design. The number of high performance electronics components such as high performance processors packaged inside servers has steadily increased, thereby increasing the amount of heat generated and dissipated during the ordinary operations of the servers. The reliability of servers used within a data center decreases if the environment in which they operate is permitted to increase in temperature over time. Maintaining a proper thermal environment is critical for normal operations of these servers in data centers, as well as the server performance and lifetime. It requires more effective and efficient cooling solutions especially in the cases of cooling high performance servers.

A server rack in a data center may contain servers having different types of electronic components that generate heat that needs to be removed by a cooling system. Different electronic components can have substantially differing thermal loads. Typically, heat generated within a server system, or a rack of server systems, is removed using a single-phase cooling system. A single-phase cooling system is a cooling system in which the coolant, or working fluid, remains in a liquid state. The rack-level distribution of coolant to remove heat is a single failure point.

In the prior art, rack-level cooling is performed by a single-phase system that pumps coolant to the server rack and transfers heat to the coolant. The coolant is then returned to a cooling system to remove the heat from the coolant. A speed of the pump that pumps coolant to the server rack may need to be varied to remove variable amounts of heat generated by components within the server rack. As the heat load increases, the pump speed may not be able to be further increased. Further, increasing the pump speed beyond a certain design point becomes an inefficient way to remove heat. In addition, the pump may fail thereby causing the single-phase system to be unable to remove heat from the heat-generating components. Thus, whether by failure of the pump to operate, or the pump being unable to be run fast enough to remove the amount of heat generated, the single-phase system may include a single point of failure for cooling the heat-generating components within the server rack in existing cooling systems.

### BRIEF DESCRIPTION OF THE DRAWINGS

Embodiments of the invention are illustrated by way of example and not limitation in the figures of the accompanying drawings in which like references indicate similar elements.

FIG. 1A is a block diagram illustrating an example of a rack architecture for multiple mixed thermal systems according to one embodiment.

FIG. 1B is a block diagram illustrating an example of a rack architecture for multiple mixed thermal systems according to one embodiment.

FIG. 1C is a block diagram illustrating an example of a data center architecture for multiple mixed thermal systems according to one embodiment.

FIG. 2 is a block diagram illustrating an example of a side view of an electronic rack according to one embodiment.

FIG. 3 is a block diagram illustrating an example of a top view of an electronic rack accordance to one embodiment.

FIG. 4 is a block diagram illustrating an example of a cold plate configuration according to one embodiment.

### DETAILED DESCRIPTION

Various embodiments and aspects of the inventions will be described with reference to details discussed below, and the accompanying drawings will illustrate the various embodiments. The following description and drawings are illustrative of the invention and are not to be construed as limiting the invention. Numerous specific details are described to provide a thorough understanding of various embodiments of the present invention. However, in certain instances, well-known or conventional details are not described in order to provide a concise discussion of embodiments of the present inventions.

Reference in the specification to “one embodiment” or “an embodiment” means that a particular feature, structure, or characteristic described in conjunction with the embodiment can be included in at least one embodiment of the invention. The appearances of the phrase “in one embodiment” in various places in the specification do not necessarily all refer to the same embodiment.

In a first aspect, an electronic rack cooling system is configured to cool heat-generating components in a plurality of servers in an electronic rack. The cooling system includes a condenser of a two-phase cooling system coupled to a facility cooling fluid supply. The condenser is configured to continuously cool vapor returned from a two-phase cooling loop coupled between the two-phase cooling system and a two-phase coolant distribution manifold within the electronic rack. The cooling system also includes a single-phase cooling loop coupled to the facility cooling fluid supply via a flow control system. The single-phase cooling loop is coupled to the single-phase coolant distribution manifold within the electronic rack. The cooling system also includes a controller to control a flow rate of the single-phase cooling fluid from the flow control system to the single-phase cooling loop, in response to a temperature determined by the controller. The flow control system can include a two-way control valve, a coolant pump, or both the two-way control valve and the coolant pump. The two-phase cooling system can be integrated with the electronic rack. The controller can control the flow control system to prevent flow of single-phase cooling fluid to the single-phase cooling loop, in response to the temperature being below a predetermined threshold. The controller can also control the flow control system to adjust an amount of single-phase cooling fluid delivered to the single-phase cooling loop, in response to variations in the temperature. In an embodiment, the single-phase coolant loop is coupled to the plurality of servers within the electronic rack via the single-phase distribution manifold in the electronic rack and the two-phase coolant loop is coupled to the plurality of servers via the two-phase distribution manifold in the electronic rack. In an embodiment, both the single-phase cooling loop and the two-phase cooling loop are coupled to a same heat-generating component within in a server of the plurality of servers. The controller can be integrated into the electronic rack.

In a second aspect, an electronic rack cooling system can be configured to cool heat-generating components in a plurality of servers in an electronic rack. The cooling system can include a coolant pump coupled to a facility cooling system fluid supply. A condenser of a two-phase cooling system can be coupled to an output of the coolant pump. The condenser is configured to continuously cool vapor returned from a two-phase cooling loop coupled between the two-phase cooling system and a two-phase coolant distribution manifold within the electronic rack. The cooling system can also include a flow control device coupled to the output of the coolant pump. A single-phase cooling loop can be coupled to the facility cooling fluid supply via the flow control device and the single-phase cooling loop is coupled to a single-phase coolant distribution manifold within the electronic rack. The cooling system can also include a controller that is configured to control a flow rate of the single-phase cooling fluid from the flow control device to the single-phase cooling loop, in response to a temperature determined by the controller. In an embodiment the flow control device can be a two-way control valve. The two-phase cooling system, the coolant pump, and the flow control device can be integrated with the electronic rack. In an embodiment, the controller can control the flow control device to prevent flow of single-phase cooling fluid to the single-phase cooling loop in response to the temperature being below a predetermined threshold. In embodiment, the control system can adjust an amount of single-phase cooling fluid delivered to the single-phase cooling loop in response to variations in the temperature. In an embodiment, a flow rate of the coolant pump can be set to a pre-set value. The single-phase coolant loop can be coupled to the plurality of servers within the electronic rack via the single-phase distribution manifold in the electronic rack. The two-phase coolant loop is coupled to the plurality of servers via the two-phase distribution manifold in the electronic rack. In an embodiment, both the single-phase cooling loop and the two-phase cooling loop can be coupled to a same heat-generating component within in a server of the plurality of servers.

In a third aspect, a server cluster cooling system can include a plurality of electronic racks, each electronic rack having an electronic rack cooling system as described in the first aspect, above. Each electronic rack can include one or more servers, and the servers in the plurality of electronic racks can be configured to operate as the server cluster.

In a fourth aspect, a server cluster cooling system can include a plurality of electronic racks each having an electronic rack cooling system as described above in the second aspect. Each electronic rack can include one or more servers, and the servers in the plurality of racks can be configured to operate as the server cluster.

In a fifth aspect, a data center has a plurality of electronic racks each containing a plurality of heat-generating components that are cooled by a cooling system. Each electronic rack includes an indirect cooling system having a condenser coupled to a facility cooling fluid supply. The indirect cooling system has a two-phase cooling loop coupled to the condenser and to the electronic rack. The two-phase cooling loop recirculates two-phase cooling fluid to the electronic rack and back to the condenser of the indirect cooling system. In an embodiment, each electronic rack in the data center further includes a direct single-phase cooling loop coupled to the facility cooling fluid supply, via cooling fluid management components, and coupled to the electronic rack. The single-phase cooling loop recirculates single-phase cooling fluid to the electronic rack and back to a facility cooling fluid return. The cooling fluid management components include a coolant pump and a flow control device that regulate the flow of single-phase cooling fluid within the single-phase cooling loop. In an embodiment, each electronic rack in the data center further includes a rack controller that controls each of the cooling fluid management components to regulate flow of the single-phase cooling fluid within the single-phase cooling loop.

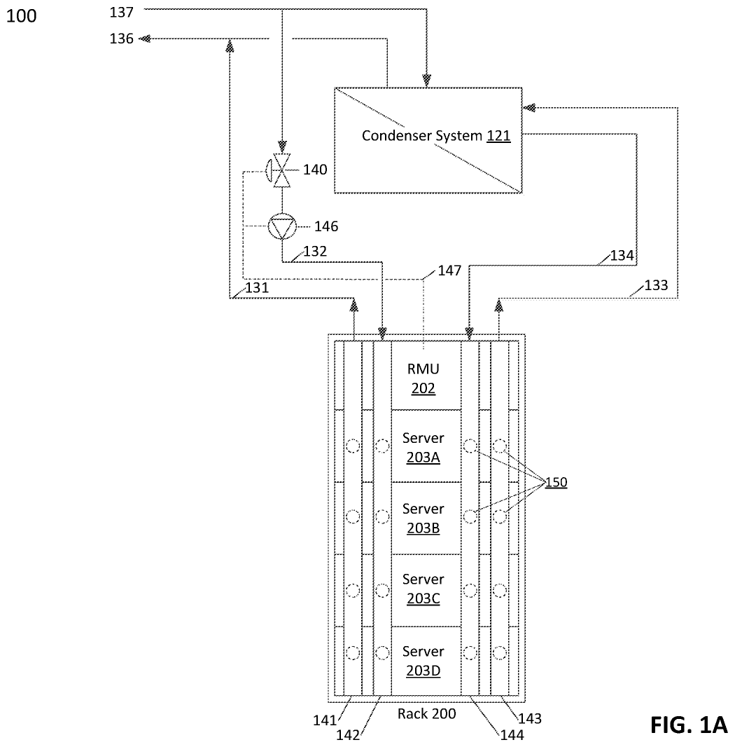

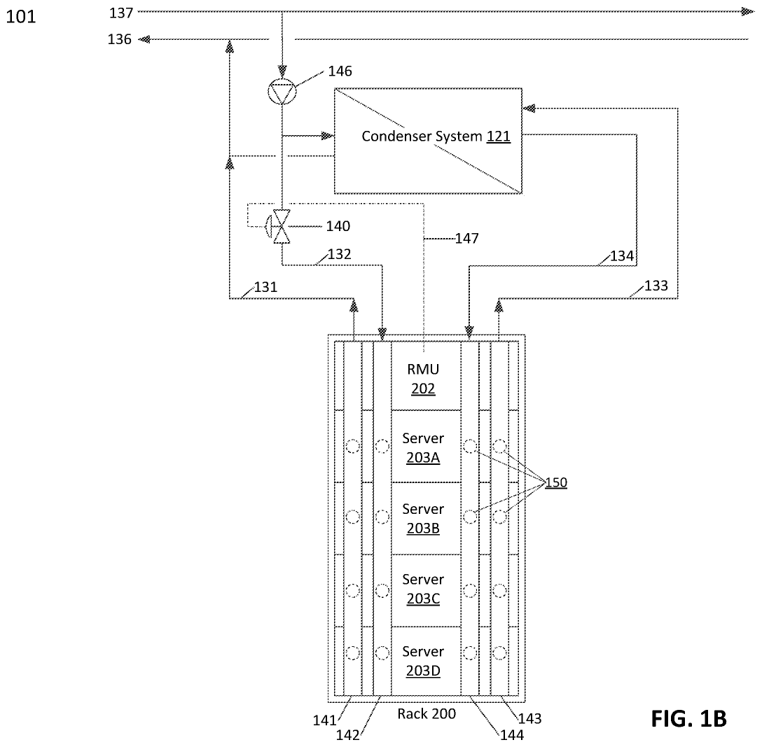

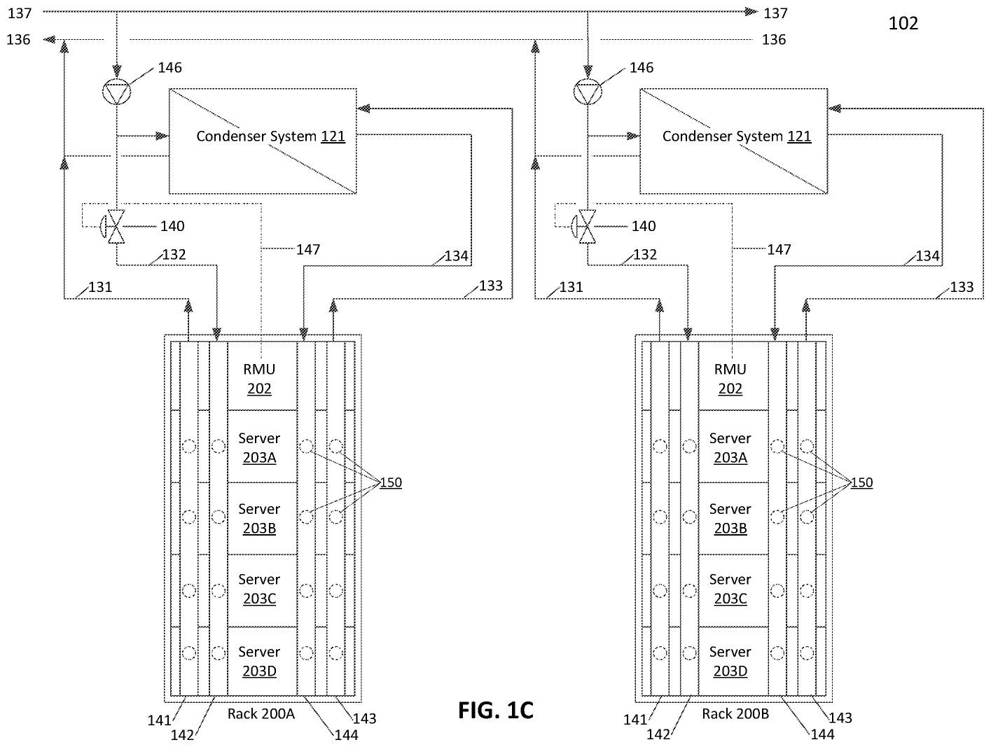

FIG. 1A is a block diagram illustrating an example of a cooling system 100 for an electronic rack 200 according to one embodiment. A cooling system 100 for an electronic rack 200 includes a two-phase cooling system (“condenser system”) 121 and a single-phase cooling loop 132/131. Facility cooling fluid supply 137 and facility fluid cooling return 136 flow continuously through the condenser system 121. Facility cooling fluid supply 137 is a single-phase cooling fluid that is selected such that the single-phase cooling fluid will not evaporate in the presence of cooling system 100 design temperatures. A flow rate of the single-phase cooling loop 132/131 is controlled by a flow control device 140 and/or a coolant pump 146. The flow control device 140 receives single-phase cooling fluid supply from facility cooling fluid supply 137.

Two-phase cooling system 121 has as two-phase cooling loop 134/133 that includes two-phase coolant supply 134 and vapor return 133 that run to, and from, the electronic rack 200, respectively. The two-phase cooling loop 134/133 flows continuously to and from the condenser system 121 and electronic rack 200. The single-phase cooling loop 132/131 includes single-phase cooling liquid supply 132 and single-phase cooling fluid return 131 that run to, and from, the electronic rack 200, respectively in accordance with a flow rate determined by the flow control device 140 and coolant pump 146. In an embodiment, the condenser system 121 can be integrated into, or onto, electronic rack 200. In an embodiment, the flow control device 140 and the coolant pump 146 can also be integrated into, or onto, electronic rack 200.

Two-phase coolant supply 134 of condenser system 121 couples to a two-phase coolant supply distribution manifold 144 that is mounted in the electronic rack 200. Vapor return 133 couples to a vapor return manifold 143 that is mounted in the electronic rack 200. Single-phase cooling fluid supply 132 is coupled to a single-phase cooling supply liquid distribution manifold 142 that is mounted in the electronic rack 200. Single-phase cooling fluid return 131 is coupled to a single-phase cooling return liquid manifold 141 that is mounted in the electronic rack 200.

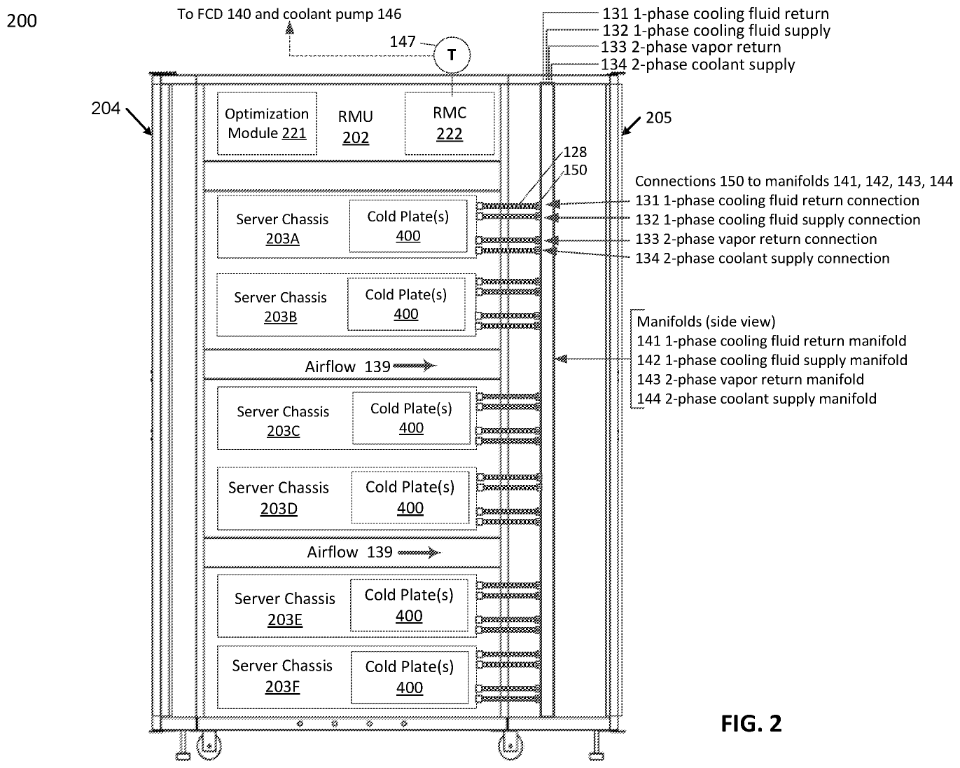

The electronic rack 200 includes a rack management unit (RMU) 202 and one or more servers, e.g. servers 203A-203D (collectively, and individually, “server 203,” unless otherwise indicated). RMU 202 includes a rack management controller (RMC) 222 that performs control functions within electronic rack 200 and for the condenser system 121, flow control device 140, and coolant pump 146. Flow rate of the flow control device 140 can be set by the rack management controller (RMC) 222 in rack management unit (RMU) 202. The flow rate of single-phase cooling fluid in the single-phase cooling loop 132/131 can be set in response to a temperature determined by the RMC 222. RMU 202 is described in detail, below, with reference to FIG. 2.

Each server 203 has connections on the server 203 chassis to couple to each of single-phase cooling fluid supply distribution manifold 142, single-phase cooling fluid return manifold 141, two-phase coolant supply distribution manifold 144, and vapor return manifold 143, via connection points 150. Inside each server 203, one or more cold plates (not shown) are coupled to the server 203 chassis coolant connection points (not shown) for single-phase cooling fluid supply 132, single-phase cooling fluid return 131, two-phase coolant supply 134, and vapor return 133. Inside each server 203, one or more heat-generating components (not shown) are coupled to the cold plate(s) (not shown). Heat-generating components can include general purpose processors, graphics processors, data processing or artificial intelligence processors, memory, communications devices, and the like. Some of these heat-generating components are coupled to the one or more cold plate(s) or other heat-removal device(s) in each server 203. The cold plate(s) remove heat from the one or more heat-generating components using both the two-phase cooling loop and the single-phase cooling loop. In an embodiment, heat may additionally be removed from the heat-generating components using air flow, thermo-electric (TE) coolers, or other devices.

Two-phase cooling fluid 134 is provided continuously by the condenser system 121 to the electronic rack 200. Heat from heat-generating components is returned to the condenser system 121 as, e.g., vapor 133 returned by the two-phase cooling loop. Vapor 133 returned to the condenser system 121 is cooled at the condenser system 121 using facility cooling fluid supply 137 which continuously flows to the condenser system 121. Heat is transferred by the condenser system 121 to facility cooling fluid return 136. Facility cooling fluid return 136 is returned to a facility heat-removal system such as a cooling tower, counter-flow heat exchanger, chiller, cooling pond, or other facility-scale cooling system (not shown). Facility cooling fluid return 136, cooled by the facility heat-removal system, is recycled back to the condenser system 121 as facility cooling fluid source 137.

In an embodiment, flow control device 140 can be a flow control valve, such as a controllable gate valve, plug valve, need valve, or other valve body type. The coolant pump 146 can be a centrifugal pump, a constant displacement pump, or other type of coolant pump 146. One or more control signals 147 are generated by the RMC 222 to set the flow rate of the flow control device 140 and flow rate of the coolant pump 146. RMC 222 is described below with reference to FIG. 2. The control signal(s) 147 to control the flow control device 140 flow rate and the coolant pump 146 flow rate can be directly generated from a temperature sensor in a server 203, such as a temperature sensor (not shown) within a chip case or cold plate (not shown) within server 203. RMC 222 can determine a control signal 147 from one or more temperature sensor (not shown) outputs from one or more chip cases or cold plates (not shown) within servers 203A-203D. RMC 222 also enables control of ON and OFF states of the flow control device 140 and the coolant pump 146.

In an embodiment, the single-phase cooling fluid in the single-phase cooling loop 132/131 is a first working fluid having a vaporization temperature that is higher than a design temperature for the cooling loop, such that the single-phase cooling fluid in the first cooling loop is not designed to vaporize during normal, design, heat loads. In an embodiment, the working fluid in a two-phase coolant supply 134 is selected such that the working fluid will vaporize at a temperature that is within a design operating range of a plurality of heat-generating components within the one or more servers 203 in the electronic rack 200.

FIG. 1B is a block diagram illustrating an example of cooling system 101 for an electronic rack 200 according to one embodiment. The cooling system 101 for the electronic rack 200 can be substantially as disclosed above for cooling system 100, with respect to FIG. 1A, with the following additional and/or different features.

The cooling system 100 for electronic rack 200 again includes a two-phase “condenser” cooling system 121 having a two-phase cooling loop with having two-phase coolant supply 134 and vapor return 133. The cooling system 101 further includes a separate single-phase cooling loop having single-phase cooling fluid supply 132 and single-phase cooling fluid return 131.

Facility cooling fluid source 137 is a single-phase cooling fluid. In FIG. 1B, the flow of facility cooling fluid from the source 137 to the condenser system 121 and to the single-phase cooling loop is determined by a flow rate setting of coolant pump 146. An inlet port of coolant pump 146 is coupled to facility cooling fluid source 137. An outlet port of coolant pump 146 is coupled (1) to an inlet connection of condenser system 121 and (2) to a flow control device (“FCD”) 140. An outlet port of flow control device 140 is coupled to a single-phase cooling fluid supply manifold 142 mounted in the electronic rack 200. An amount of facility cooling liquid 137 provided to condenser system 121 is first determined by a flow rate setting of the coolant pump 146. A flow rate of the coolant pump 146 sets a maximum flow rate of single-phase cooling fluid 137 that will be shared between the two-phase condenser system 121 and the single-phase cooling loop 132/131. A flow rate setting for the flow control device 140 determines how much of the maximum flow rate from the coolant pump 146 will be sent to single-phase cooling fluid 132/131 that is coupled to the distribution manifolds 142/141. In an embodiment, single-phase cooling loop 132/131 is supplemental to the continuously-circulating two-phase cooling loop 134/133, such that flow control device can be set to fully closed (zero flow rate). In an embodiment, RMC 222 also enables control of ON and OFF states of the flow control device 140 and/or the coolant pump 146. RMC 222 also controls a variable open position of the flow control device 140 and a variable speed of the coolant pump 146. RMC 222 can set the flow control device 140 to a closed position, set the coolant pump to an ON state, and adjust a speed of coolant pump 146. In an embodiment, when the temperature increases, RMC 222 can first start to increase the pump speed and still maintain the flow control device 140 in a closed position (OFF state). As the temperature continues to increase to a higher value, RMC 222 can open the flow control device 140, thereby directing single-phase cooling fluid directly to the electronic rack via the single-phase cooling loop 132/131.

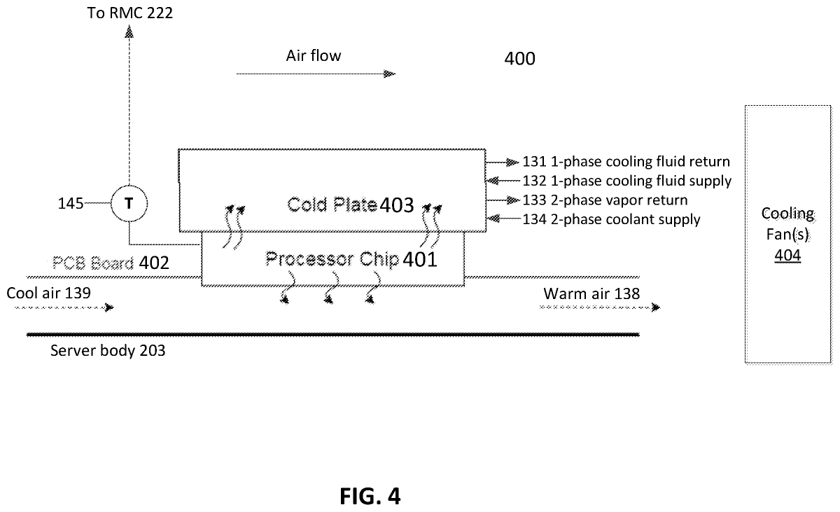

In an embodiment, a flow rate of the coolant pump 146 can be set manually. In an embodiment, a control signal (not shown) from the rack management controller (RMC) 222 within the rack management unit 202 can control the coolant pump 146 flow rate setting via a control signal set through an administrative software. In an embodiment, the coolant pump 146 flow rate can be set by the RMC 222 in response to one or more temperature(s) 145 of chip cases in servers 203 as shown in FIG. 4, below.

As described above, one or more heat-generating components within each server 203 in an electronic rack 200 are coupled to a cold plate and can have a temperature sensor either in, or on a chip case of the heat-generating component. The cold plate(s) can use both the single-phase coolant loop 132/131 and two-phase cooling loop 134/133 to cool the heating generating devices coupled to the cold plate. In an embodiment, the single-phase flow control device 140 can be set to a zero gpm flow rate, such that only two-phase cooling fluid flows through the cold plate(s). Chip case temperature(s) can be sent to the rack RMC 222 to generate a control signal to the flow control device 140 to set a flow rate for flow control device 140. As the RMC 222 determines that the temperature(s) rise, the flow rate for flow control device 140 can be increased.

In an embodiment, the flow control device 140 flow rate setting can be a fixed percentage of the flow rate setting for the coolant pump 146. For example, the flow control device 140 may be set for a flow rate that is 50% of the coolant pump 146 flow rate. In another embodiment, the flow rate of the flow control device may be determined from a calibration table that correlates a temperature determined by the RMC 222 with a flow rate for the coolant pump 146. In an embodiment, RMC 222 can include one or more artificial intelligence (“AI”) models that train to correlate RMC 222 temperature changes, coolant pump 146 flow rates, and a flow rate of flow control device 140, to minimize temperatures determined by RMC 222. In an embodiment, one or more AI models can additionally, or alternatively, minimize energy consumption, such as energy consumption due to operation of the coolant pump 146 and for actuating the flow control device 140.

FIG. 1C is a block diagram illustrating two systems as described above in FIG. 1B. In another embodiment, additional systems can be added, either of the type described in FIG. 1A or 1B, above. In such an embodiment, a number of servers according to FIGS. 1A and/or 1B can be configured as a server cluster within a data center (not shown). In an embodiment, the number of electronic racks according to FIGS. 1A and/or 1B can be configured as a data center system (not shown). The number of electronic racks configured as a cluster or data center is not limited. In FIG. 1C, facility cooling fluid source 137 provides facility cooling fluid 137 to the coolant pump 146 of each electronic racks 200A and 200B. Electronic racks 200A and 200B may have a different number of servers 203 in their respective racks. Each server 203 within each rack can have different number and type of heat-generating components than other servers 203. Single-phase cooling fluid return 131 from the electronic rack is returned to facility cooling fluid return 136. Single-phase cooling fluid 136 that is returned from the condenser system 121 is also returned to facility cooling fluid return 136. Facility cooling fluid return 136 is routed to a facility cooling system (not shown). Other features of electronic racks 200A and 200B, or other additional racks (not shown) are substantially identical to FIG. 1B (in the case racks 200A and 200B, shown in FIG. 1C) or FIG. 1A, if such racks are added to the embodiment of FIG. 1C. In an embodiment, each of the electronic racks 200 in the server cluster or data center can include different fluid control components coupled between the facility cooling fluid supply 137 and facility cooling fluid return 136 and the single-phase cooling loop manifolds 141 and 142 in each electronic rack 200.

FIG. 2 is block diagram illustrating an electronic rack 200 according to one embodiment. Electronic rack 200 may represent any of the electronic racks 200, as shown in FIGS. 1A-1C. Referring to FIG. 2, according to one embodiment, electronic rack 200 includes, but is not limited to, rack management unit (RMU) 202, and one or more server chassis 203A-203F (collectively, and individually, referred to as server chassis 203, unless otherwise indicated). Server chassis 203 can be inserted into an array of server slots (e.g., standard shelves) respectively from frontend 204 or back end 205 of electronic rack 200. Note that although there are six server chassis 203A-203F shown here, more or fewer server chassis may be maintained within electronic rack 200. In one embodiment, electronic rack 200 can be either open to the environment or partially contained by a rack container, as long as the cooling fans can generate airflows from the frontend to the back end.

In addition, for at least some of the server chassis 203, an optional fan module (not shown) is associated with the server chassis. Each of the fan modules includes one or more cooling fans. The fan modules may be mounted on the back ends of server chassis 203 or on the electronic rack to generate airflows flowing from frontend 204, traveling through the air space of the sever chassis 203, and existing at backend 205 of electronic rack 200.

Each of server chassis 203 may include one or more IT components (e.g., central processing units or CPUs, general/graphic processing units (GPUs), memory, and/or storage devices). Each IT component may perform data processing tasks, where the IT component may include software installed in a storage device, loaded into the memory, and executed by one or more processors to perform the data processing tasks. Server chassis 203 may include a host server (referred to as a host node) coupled to one or more compute servers (also referred to as computing nodes, such as CPU server and GPU server). The host server (having one or more CPUs) typically interfaces with clients over a network (e.g., Internet) to receive a request for a particular service such as storage services (e.g., cloud-based storage services such as backup and/or restoration), executing an application to perform certain operations (e.g., image processing, deep data learning algorithms or modeling, etc., as a part of a software-as-a-service or SaaS platform). In response to the request, the host server distributes the tasks to one or more of the computing nodes or compute servers (having one or more GPUs) managed by the host server. The computer servers perform the actual tasks, which may generate heat during the operations.

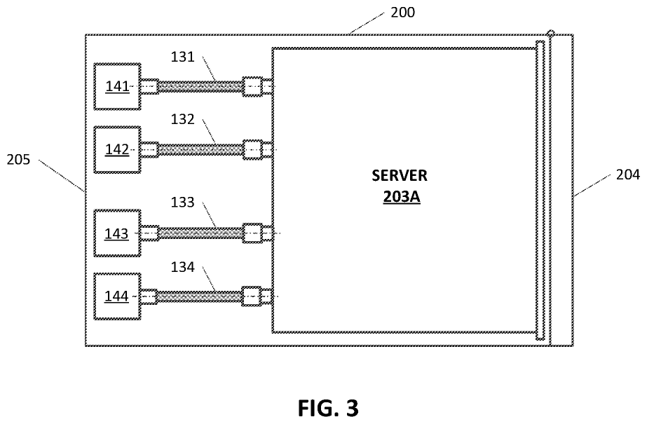

Electronic rack 200 further includes optional RMU 202 configured to provide and manage power supplied to servers 203. RMU 202 may be coupled to a power supply unit (not shown) to manage the power consumption of the power supply unit. The power supply unit may include the necessary circuitry (e.g., an alternating current (AC) to direct current (DC) or DC to DC power converter, battery, transformer, or regulator, etc.,) to provide power to the rest of the components of electronic rack 200. RMU can include a temperature, or control, signal 147 that is sent to the flow control device (FCD) 140 and, optionally, to the coolant pump 146. The temperature signal 147 can be derived from one or more temperature signals (now shown) from chip cases of heat-generating components and/or cold plates 400 (not shown). See, FIG. 3, below, for more details on the temperature of chip cases, cold plates, and heat-generating components.

In one embodiment, RMU 202 includes optimization module 221 (not shown) and rack management controller (RMC) 222. RMC 222 may include a monitor to monitor operating status of various components within electronic rack 200, such as, for example, servers 203, and the fan modules. Specifically, the RMC 222 receives operating data from various sensors representing the operating environments of electronic rack 200. For example, the monitor may receive operating data representing temperatures of the processors, cooling liquid, and airflows, which may be captured and collected via various temperature sensors. The monitor may also receive data representing the fan power and pump power generated by the fan modules 231 and liquid pump 212, which may be proportional to their respective speeds. These operating data are referred to as real-time operating data. Note that the monitor may be implemented as a separate module within RMU 202.

Note that the rack configuration as shown in FIG. 2 is shown and described for the purpose of illustration only; other configurations or arrangements may also be applicable. The cold plates 400 of server chassis 203 may be coupled to a rack manifold, e.g. coolant distribution and return manifolds 141-144 of the single-phase (“1-phase”) cooling loop 132/131 and two-phase (“2-phase”) cooling loop 134/133 described above. Each server 203 can be coupled to manifolds 141-143 at a connection 150 using a connection hose or piping 128. Each server 203 can route single-phase cooling fluid supply and return 132/131 (“the single-phase cooling loop”) to one or more cold plates and can also route two-phase coolant supply and vapor return 134/133 (“the two-phase cooling loop”) to one or more cold plates in server 203. In an embodiment, one or more, or all, cold plates can be coupled to both the single-phase cooling loop and the two-phase cooling loop.

FIG. 3 is a block diagram illustrating a top view of a sever 203A in an electronic rack 200, according to one embodiment. The front of the electronic rack 200 is labeled 204, while the rear of the electronic rack is labeled 205. As described above, a single-phase cooling loop can include a single-phase cooling fluid supply line 132 and a single-phase cooling fluid return line 131. The single-phase cooling fluid supply line 132 can be coupled to a manifold 142 installed in the rear 205 of the electronic rack 200 using, e.g. a hose connection. The single-phase cooling fluid return line 131 can be coupled to manifold 141 using e.g. a hose connection. Similarly, the two-phase cooling loop has two-phase cooling fluid supply 134 that can be coupled to manifold 144. The vapor return line 133 of the two-phase loop can be coupled to manifold 143 using e.g. a hose connection. Heat generating devices (not shown) within any server 203 can be coupled to a cold plate (not shown) within the server 203 that is cooled by both the single-phase cooling loop and the two-phase cooling loop. Heat-generating components can, in an embodiment, additionally be cooled by air flow, thermoelectric (TE) coolers, and the like. The design of the cooling plate for running two cooling loops is not the subject of the present disclosure.

FIG. 4 is a block diagram illustrating a processor cold plate configuration according to one embodiment. The processor/cold plate assembly 400 can represent any of the processors/cold plate structures of server chassis 203 as described above. Referring to FIG. 4, processor 401 is plugged onto a processor socket mounted on printed circuit board (PCB) or motherboard 402 coupled to other electrical components or circuits of a data processing system or server. Processor chip 401 can be mounted to a chip case having a temperature sensor 145 that sends a temperature signal to RMC 222. RMC 222 can use a mathematical derivation to determine a single temperature value to use for determining a control signal to the flow control device 140. The single temperature can be selected, by the RMC 222, as being a highest temperature from all chip case temperatures received from servers 203 chip cases. The single temperature can be an average, or a weighted average, of all chip case temperatures received from servers 203 chip cases. In an embodiment, RMC 222 can select one or more specific chip case temperatures from all available chip case temperatures to use in determining a single temperature for determining a control signal to the flow control device 140.

Processor 401 also includes a cold plate 403 attached to it, which is coupled to a plurality of rack manifolds (not shown) that are coupled to single-phase cooling fluid supply line 132 and single-phase cooling fluid return line 131, and two-phase coolant supply line 134 and vapor return line 133. A portion of the heat generated by processor 401 is removed by the cooling liquid(s) via cold plate 403. The remaining portion of the heat enters into an air space underneath or above, which may be removed by an airflow 139 generated by cooling fan 404. The cool air 139 passes through the air space which heats the air to become warm air 138, which is exhausted out the back of the electronic rack 200 (not shown) in which the server 203 is installed.

In the foregoing specification, embodiments of the invention have been described with reference to specific exemplary embodiments thereof. While rack orientations are shown as horizontal, this is not limiting. Different server rack orientations, e.g. vertical, or upward/downward, can be implemented using this disclosure. It will be evident that various modifications may be made thereto without departing from the broader spirit and scope of the invention as set forth in the following claims. The specification and drawings are, accordingly, to be regarded in an illustrative sense rather than a restrictive sense.

In the foregoing specification, embodiments of the invention have been described with reference to specific exemplary embodiments thereof. Different selection of male/female connectors, connectors types, hose, tubing, piping, and structural frame members, and orientations of assemblies can be implemented by one of skill in the art in possession of this disclosure. While rack orientations are shown as horizontal, this is not limiting. Different server rack orientations, e.g. vertical, or upward/downward, can be implemented using this disclosure. It will be evident that various modifications may be made thereto without departing from the broader spirit and scope of the invention as set forth in the following claims. The specification and drawings are, accordingly, to be regarded in an illustrative sense rather than a restrictive sense.

What is claimed is:

1. An electronic rack cooling system configured to cool heat-generating components in a plurality of servers in an electronic rack, the cooling system comprising:
a condenser of a two-phase cooling system coupled to a facility cooling fluid supply, the condenser configured to cool vapor returned from a two-phase cooling loop coupled between the two-phase cooling system and a two-phase coolant distribution manifold within the electronic rack;
a single-phase cooling loop coupled to the facility cooling fluid supply via a flow control system, the single-phase cooling loop coupled to a single-phase coolant distribution manifold within the electronic rack; and
a controller to control a flow rate of a single-phase cooling fluid from the flow control system to the single-phase cooling loop, in response to a temperature determined by the controller.

2. The electronic rack cooling system of claim 1, wherein the flow control system comprises:
a two-way control valve;
a coolant pump; or
both the two-way control valve and the coolant pump.

3. The electronic rack cooling system of claim 1, wherein in the two-phase cooling system is integrated with the electronic rack.

4. The electronic rack cooling system of claim 1, wherein the controller controls the flow control system to prevent flow of single-phase cooling fluid to the single-phase cooling loop, in response to the temperature being below a predetermined threshold.

5. The electronic rack cooling system of claim 1, wherein the controller controls the flow control system to adjust an amount of the single-phase cooling fluid delivered to the single-phase cooling loop in response to variations in the temperature.

6. The electronic rack cooling system of claim 5, wherein the single-phase cooling loop is coupled the plurality of servers within the electronic rack via the single-phase distribution manifold in the electronic rack and the two-phase coolant loop is coupled to the plurality of servers via the two-phase distribution manifold in the electronic rack.

7. The electronic rack cooling system of claim 1, wherein both the single-phase cooling loop and the two-phase cooling loop are coupled to a same heat-generating component within in a server of the plurality of servers.

8. The electronic rack cooling system of claim 7, wherein the facility cooling fluid supply is controlled to cool the electronic rack directly, or in a combination of direct cooling with the single-phase cooling loop and indirect cooling using the condenser of the two-phase cooling system and the two-phase cooling loop.

9. An electronic rack cooling system configured to cool heat-generating components in a plurality of servers in an electronic rack, the cooling system comprising:
a coolant pump coupled to a facility cooling system fluid supply;
a condenser of a two-phase cooling system coupled to an output of the coolant pump, the condenser configured to cool vapor returned from a two-phase cooling loop coupled between the two-phase cooling system and a two-phase coolant distribution manifold within the electronic rack;
a flow control device coupled to the output of the coolant pump;
a single-phase cooling loop coupled to the facility cooling fluid supply via the flow control device, the single-phase cooling loop coupled to a single-phase coolant distribution manifold within the electronic rack; and
a controller configured to control a flow rate of a single-phase cooling fluid from the flow control device to the single-phase cooling loop, in response to a temperature determined by the controller.

10. The electronic rack cooling system of claim 9, wherein the flow control device comprises a two-way control valve.

11. The electronic rack cooling system of claim 9, wherein the two-phase cooling system, the coolant pump, and the flow control device are integrated with the electronic rack.

12. The electronic rack cooling system of claim 9, wherein the controller controls the flow control device to prevent flow of the single-phase cooling fluid to the single-phase cooling loop in response to the temperature being below a predetermined threshold.

13. The electronic rack cooling system of claim 9, wherein the controller controls the control system to adjust an amount of the single-phase cooling fluid delivered to the single-phase cooling loop in response to variations in the temperature.

14. The electronic rack cooling system of claim 13, wherein a flow rate of the coolant pump is set to a pre-set value.

15. The electronic rack cooling system of claim 9, wherein the controller controls a speed of the coolant pump to change a flow rate of the coolant pump.

16. The electronic rack cooling system of claim 9, wherein the single-phase coolant loop is coupled to the plurality of servers within the electronic rack via the single-phase distribution manifold in the electronic rack and the two-phase coolant loop is coupled to the plurality of servers via the two-phase distribution manifold in the electronic rack.

17. The electronic rack cooling system of claim 9, wherein both the single-phase cooling loop and the two-phase cooling loop are coupled to a same heat-generating component within in a server of the plurality of servers.

18. A data center, comprising:
a facility cooling fluid supply;
a plurality of electronic racks each containing a plurality of heat-generating components; and
for each of the electronic racks, an indirect cooling system including a condenser coupled to the facility cooling fluid supply, wherein the indirect cooling system includes a two-phase cooling loop coupled between the electronic rack and the condenser that recirculates two-phase cooling fluid to the electronic rack and back to the indirect cooling system.

19. The data center of claim 18, further comprising, for each electronic rack,
a direct single-phase cooling loop coupled to the facility cooling fluid supply, via cooling fluid management components, and coupled to the electronic rack,
wherein the single-phase cooling loop recirculates single-phase cooling fluid to the electronic rack and back to a facility cooling fluid return, and the cooling fluid management components include a coolant pump and a flow control device that regulate the flow of single-phase cooling fluid within the single-phase cooling loop.

20. The data center of claim 19, further comprising, for each electronic rack, a rack controller that controls each of the cooling fluid management components to regulate flow of a single-phase cooling fluid within the single-phase cooling loop.
